(19) United States
(12) Patent Application Publication
(10) Pub. No.: US 2019/0363466 A1
(43) Pub. Date: Nov. 28, 2019

(54) CIRCUIT CONNECTION DEVICE, AND ELECTRONIC APPARATUS DEVICE

(71) Applicant: NGK SPARK PLUG CO., LTD., Nagoya-shi, Aichi (JP)

(72) Inventors: Hidekazu MINAMI, Kasugai-shi, Aichi (JP); Takashi KODA, Nagoya-shi, Aichi (JP); Shingo YOSHIDA, Ichinomiya-shi, Aichi (JP)

(73) Assignee: NGK SPARK PLUG CO., LTD., Nagoya-shi, Aichi (JP)

(21) Appl. No.: 16/477,692

(22) PCT Filed: Jan. 19, 2018
(86) PCT No.: PCT/JP2018/001632

§ 371 Date: Jul. 12, 2019

(30) Foreign Application Priority Data
Jan. 20, 2017 (JP) 2017-008935

(51) Int. Cl. H01R 12/51; H05K 7/12; H01R 4/18; H01R 13/66; H01R 13/42; G01K 7/00; G01N 27/409

(52) U.S. Cl. CPC H01R 12/51; H05K 7/12; H01R 4/18; G01N 27/409; H01R 13/42; G01K 7/00; H01R 13/66

(57) ABSTRACT

A circuit connection device for connecting circuit to an electronic device having one or a plurality of first terminals, circuit board, tubular case body, terminal inserting portion, terminal core and guide. The first terminal is electrically connected to circuit board. The case body accommodates circuit board and has an opening at its one end. The terminal inserting portion has a penetration hole and closes an opening of the case body. The terminal core is placed in case body. The guide is configured to guide the terminal core in an axis direction of the case body. The first terminal is inserted into the penetration hole of the terminal inserting portion. The terminal core has one or a plurality of second terminals electrically connected to the circuit board and insulating retainer retaining the second terminal. The retainer has a positioning portion that maintains a position relationship with circuit board.

### CROSS-REFERENCE OF RELATED APPLICATIONS

The present international application is an application claiming a priority of Japanese patent application No. 2017-008935 filed on Jan. 20, 2017 with Japanese Patent Office, and the entire contents of Japanese patent application No. 2017-008935 are incorporated herein by reference.

### TECHNICAL FIELD

The present invention relates to a circuit connection device.

### BACKGROUND ART

There is publicly known a structure in which, for instance, in a gas sensor device of a vehicle, a circuit board for controlling or driving a sensor is protected with a case (see Patent Document 1). In such a sensor device, not only the circuit board for controlling or driving the sensor, but also a terminal core that is a resin-molded product having a terminal that connects the circuit board and a cable etc., are placed in the case.

### CITATION LIST

### Patent Document

Patent Document 1: Japanese Unexamined Patent Application Publication No. JP2012-141300

### SUMMARY OF THE INVENTION

### Technical Problem

Depending on type or processing content of the sensor, the circuit board in the case is enlarged, then an entire length of the circuit board might be increased. In this case, since an entire length of the case is also increased, in the related art sensor device, there is a risk that adjustment of inserting positions of the circuit board and the terminal core will be difficult then this will cause a poor connection (or connection failure).

An object of the present invention is therefore to provide a circuit connection device that is capable of facilitating positioning of the circuit board and the terminal core (positioning between the circuit board and the terminal core) in the case.

### Solution to Problem

One aspect of the present invention is a circuit connection device for connecting a circuit to an electronic device. The circuit connection device comprises: one or a plurality of first terminals; a circuit board; a tubular case body; a terminal inserting portion; a terminal core; and a guide. The one or the plurality of first terminals is electrically connected the circuit board. The case body accommodates therein the circuit board and has at one end thereof an opening. The terminal inserting portion has one or a plurality of penetration holes and closes the opening of the case body. The terminal core is placed in the case body. The guide is configured to guide the terminal core in an axis direction of the case body. The one or the plurality of first terminals is inserted into the one or the plurality of penetration holes of the terminal inserting portion. The terminal core has: one or a plurality of second terminals electrically connected to the circuit board; and an insulating retainer retaining the one or the plurality of second terminals. The retainer has a positioning portion configured to maintain a position relationship with the circuit board.

According to such configuration, first, after fixing the terminal core to the terminal inserting portion, a relative position between the terminal core and the circuit board can be previously fixed by the positioning portion. Next, by inserting the terminal core and the circuit board into the case body together with the terminal inserting portion and fitting the terminal inserting portion to the case body, the terminal core and the circuit board are maintained at an intended position. Further, by the guide guiding the terminal core in the axis direction of the case body, even in a case where the case body is long, it is possible to smoothly insert the terminal core and the circuit board into the case body. It is consequently possible to facilitate the positioning of the circuit board and the terminal core (the positioning between the circuit board and the terminal core) in the case body.

According to another aspect of the present invention, the circuit board could have at least one board penetration hole. And, the positioning portion could include at least one protrusion that is fitted into the at least one board penetration hole of the circuit board. According to such configuration, it is possible to perform the positioning between the terminal core and the circuit board by a simple structure, and also to improve the workability of the positioning.

According to a further aspect of the invention, when a length of the circuit board in the axis direction of the case body is L, positioning of the circuit board by the positioning portion could be made at a position that is L/3 or more away from an end portion, located at a terminal inserting portion side, of the circuit board. According to such configuration, it is possible to prevent a position of the circuit board from shifting in the case body.

According to a still further aspect of the invention, the terminal inserting portion could have a protruding plate that protrudes inwards in the axis direction of the case body. And, the retainer could have an engaging portion that is engaged with the terminal inserting portion. Further, the engaging portion could include at least one nail that is engaged with the protruding plate of the terminal inserting portion. According to such configuration, it is possible to fix the terminal core to the terminal inserting portion easily and surely.

According to a still further aspect of the invention, the first terminal could be a crimping terminal that is fixed to a tip end of a connecting cable. And, the terminal inserting portion could have a movement restraining surface with which a top end portion of the crimping terminal is engaged. According to such configuration, an increase of a contact resistance can be suppressed, then, it is possible to reduce error of a sensor signal using minute electric current. In addition, it is possible to prevent the crimping terminal from coming off.

According to a still further aspect of the invention, an area, which is a cross section that is perpendicular to the axis direction of the case body, of an inside space of the case body could be smaller from the opening of case body toward an opposite side to the opening. According to such configuration, it is possible to improve the workability of the insertion of the terminal core and the circuit board into the case body.

Another aspect of the present invention is electronic equipment having the circuit connection device and an electronic device that is electrically connected to the one or the plurality of first terminals. According to such configuration, it is possible to improve reliability of connection between the electronic device and the circuit board.

### BRIEF DESCRIPTION OF THE DRAWINGS

FIGS. 1A and 1B are schematic perspective views showing a circuit connection device of an embodiment.

FIG. 2 is a schematic perspective exploded view of the circuit connection device of FIG. 1A.

FIG. 3A is a schematic sectional view taken along a line IIIA-IIIA of FIG. 1B. FIG. 3B is a schematic perspective view showing an example of a guide of another embodiment that is different from FIG. 3A.

FIG. 4A is a schematic plan view showing a state in which, in the circuit connection device of FIG. 1A, first terminals are placed in a first retainer. FIG. 4B is a schematic sectional view taken along a line IVB-IVB of FIG. 4A.

FIG. 5A is a schematic plan view of the first terminals, the first retainer and a second retainer of the circuit connection device of FIG. 1A. FIG. 5B is a schematic sectional view taken along a line VB-VB of FIG. 5A.

FIG. 6 is a schematic perspective view showing a circuit connection device of another embodiment that is different from FIG. 1A.

FIG. 7A is a schematic plan view of the circuit connection device of FIG. 6. FIG. 7B is a schematic side view of the circuit connection device of FIG. 6. FIG. 7C is a schematic front view of the circuit connection device of FIG. 6.

FIG. 8A is a schematic sectional view taken along a line VIIIA-VIIIA of FIG. 7A. FIG. 8B is a schematic sectional view taken along a line VIIIB-VIIIB of FIG. 7B. FIG. 8C is a schematic sectional view taken along a line VIIIC-VIIIC of FIG. 7C.

FIG. 9A is a schematic perspective view showing a terminal core of the circuit connection device of FIG. 6. FIG. 9B is a schematic perspective view of the terminal core of FIG. 9A with the terminal core reversed with respect to a Y-axis.

FIG. 10A is a schematic perspective view showing a part (a sub-assembly) in which the terminal core of the circuit connection device of FIG. 6 is fixed to a terminal inserting portion. FIG. 10B is a schematic perspective view of the sub-assembly of FIG. 10A with the sub-assembly reversed with respect to the Y-axis.

FIG. 11 is a schematic perspective view showing a circuit component having the terminal inserting portion, the terminal core and a circuit board of the circuit connection device of FIG. 6.

FIG. 12 is a schematic block diagram showing an electronic apparatus device (electronic equipment) of an embodiment.

### EXPLANATION OF REFERENCE

1, 201 . . . circuit connection device, 2, 202 . . . case body, 3, 203 . . . terminal inserting portion, 4, 5, 204 . . . connecting cable, 6, 206 . . . circuit board, 7, 207 . . . first terminal, 8 . . . terminal core, 22, 202B . . . ridge line, 32, 281A . . . movement restraining surface, 33 . . . protruding plate, 61, 206A . . . board penetration hole, 71, 271 . . . top end portion, 81, 210 . . . second terminal, 81A, 210A . . . top end portion, 81B, 210B . . . band portion, 82 . . . retainer, 82A . . . guide, 82B, 209B . . . positioning portion (protrusion), 82C, 209D . . . engaging portion, 82D, 209A . . . sandwiching surface, 83 . . . nail, 100 . . . electronic equipment, 101 . . . electronic device, 208 . . . first retainer, 209 . . . second retainer, 211 . . . seal member, 281 . . . terminal retaining portion, 282 . . . terminal holding portion, 209C . . . recessed portion.

### EMBODIMENTS FOR CARRYING OUT THE INVENTION

Embodiments to which the present invention is applied will be explained below with reference to the drawings.

### 1. First Embodiment

### [1-1. Configuration]

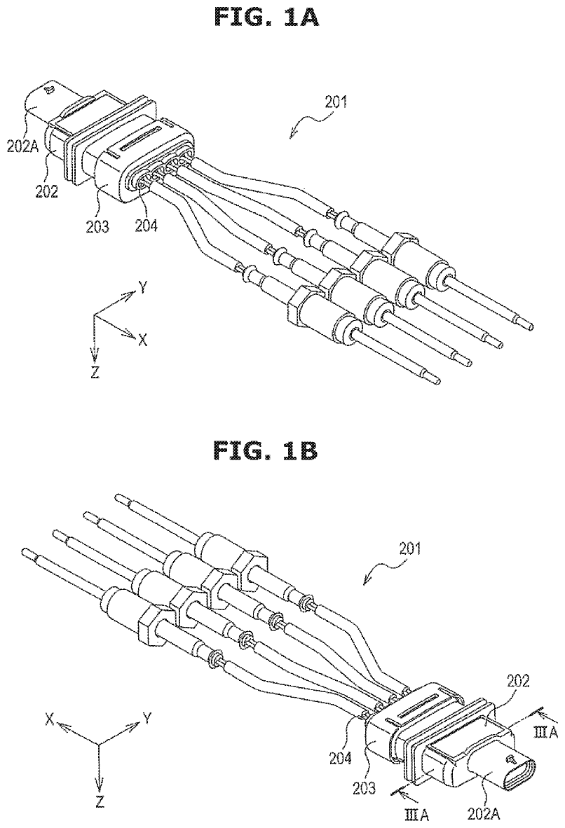

A circuit connection device 201 shown in FIGS. 1A and 1B is a device that protects a circuit board for controlling or driving an electronic device and electrically connects the circuit board to the electronic device and to a control device.

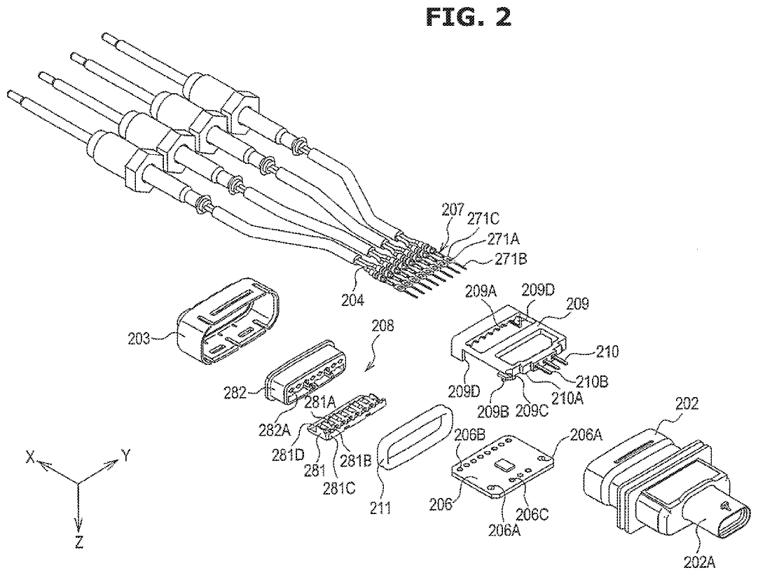

The circuit connection device 201 has, as shown in FIGS. 1A, 1B and 2, a case body 202, a terminal inserting portion 203, a plurality of connecting cables 204, a circuit board 206, a plurality of first terminals 207, a first retainer 208, a second retainer 209 and a seal member 211.

Here, the second retainer 209 and second terminals 210 form a terminal core. In the drawings, an X-axis is an axis that is parallel to a center axis of the case body 202, a Z-axis is an axis that is perpendicular to a plate surface of the circuit board 206, and a Y-axis is an axis that is perpendicular to the X-axis and the Z-axis.

<Case Body>

The case body 202 is a bottomed tubular body whose one end is an opening end and whose other end is a closed end. The case body 202 is usually made of resin.

As shown in FIGS. 1A and 1B, a direction of the center axis of the case body 202 is identical with a longitudinal direction (a direction of the X-axis in the drawings). As shown in FIG. 2, the circuit board 206, the first retainer 200, the second retainer 209 and the seal member 211 are accommodated in an inside space of the case body 202. Here, the center axis of the case body 202 means an axis that passes through a center of the case body 202 and extends from one end side to the other end side of the case body 202 (i.e. extends from the opening to an opposite side to the opening).

The case body 202 is provided, at the opposite side to the opening thereof (i.e. at a bottom portion of the tubular body), with a connector 202A to which an electronic component is electrically connected. The connector 202A extends in the X-axis direction.

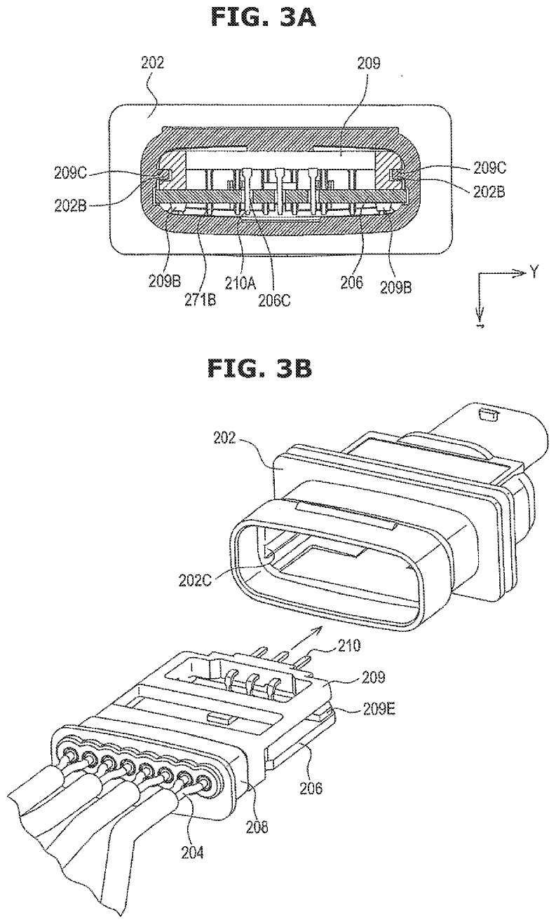

The case body 202 has, as shown in FIG. 3A, two ridge lines 202B that protrude inwards in the Y-axis direction from an inner surface of the case body 202 and extend parallel to the X-axis. These two ridge lines 202B restrain a movement in the Y-axis direction and the Z-axis direction of the second retainer 209 by top end portions of the ridge lines 202B being inserted or fitted into respective recessed portions 209C of the second retainer 209.

<Terminal Inserting Portion>

The terminal inserting portion 203 is a tubular body whose length in the center axis direction is shorter than that of the case body 202. The terminal inserting portion 203 is usually made of resin, which is the same as the case body 202.

The terminal inserting portion 203 closes the opening of the case body 202 by being fitted onto a distal end at the opening side of the case body 202. As shown in FIG. 1A, the plurality of first terminals 207 and the plurality of connecting cables 204 to which the plurality of first terminals 207 are connected are inserted into the terminal inserting portion 203. More specifically, the terminal inserting portion 203 is provided, at a bottom thereof, with a penetration hole, and the plurality of first terminals 207 and the plurality of connecting cables 204 are inserted into this penetration hole.

<Circuit Board>

As shown in FIG. 2, the circuit board 206 has a quadrangular outside shape. Here, corners of the circuit board 206 could be chamfered. The circuit board 206 is accommodated in the case body 202. A plurality of electronic components (not shown) are mounted on the circuit board 206.

The plurality of first terminals 207 and the plurality of second terminals 210 are electrically connected to the circuit board 206. The circuit board 206 sends and receives signals between the circuit board 206 and the device that is electrically connected to the plurality of first terminals 207 or the plurality of second terminals 210, and also supplies and receives power between the circuit board 206 and the device.

The circuit board 206 is provided with two positioning board penetration holes 206A into which two positioning portions 209B of the after-mentioned second retainer 209 are fitted respectively. The two board penetration holes 206A penetrate the circuit board 206 in a thickness direction of the circuit board 206.

<First Terminal>

As shown in FIG. 2, each of the plurality of first terminals 207 is a crimping terminal that is fixed to a tip end (i.e. a core wire portion) of the connecting cable 204. Top end portions 271, located at an opposite side to the connecting cables 204 of the plurality of first terminals 207 are inserted into and soldered to a plurality of through holes 206B of the circuit board 206 respectively.

Crimping portions of the first terminals 207 are inserted into respective penetration holes 282A of an after-mentioned terminal holding portion 282 of the first retainer 208. Each of the first terminals 207 has the top end portion 271 that extends toward an inside of the case body 202 while being held in the penetration hole 282A of the terminal holding portion 282.

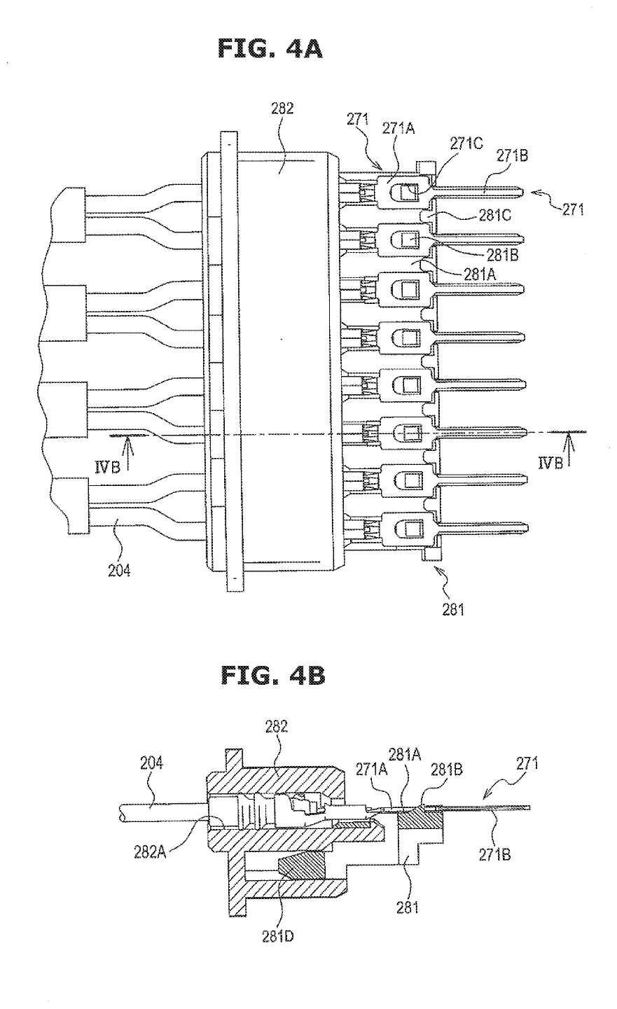

As shown in FIGS. 4A and 4B, the top end portion 271 of each first terminal 207 has a band portion 271A whose plate surface is perpendicular to the Z-axis direction and a protruding portion 271B which protrudes from a terminal retaining portion 281. The band portion 271A has, at the middle in a width direction thereof, a penetration opening 271C that penetrates the band portion 271A in the Z-axis direction.

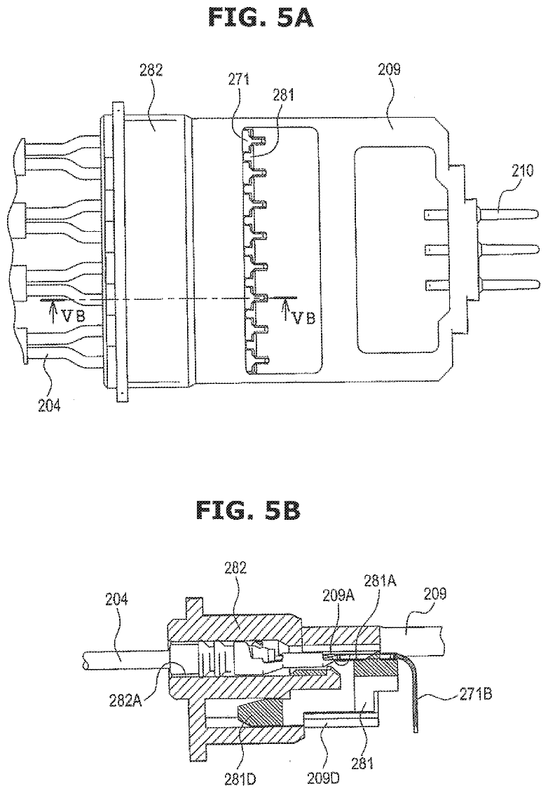

As shown in FIGS. 5A and 5B, the band portions 271A are sandwiched and supported between a movement restraining surface 281A of the terminal retaining portion 281 of the first retainer 208 and a plurality of sandwiching surfaces 209A of the after-mentioned second retainer 209.

The protruding portion 271B is a part that extends from an X-axis direction end portion of the band portion 271A. A width of the protruding portion 271B is smaller than that of the band portion 271A. The protruding portion 271B is bent in the Z-axis direction toward the circuit board 206.

<First Retainer>

The first retainer 208 is an insulating member placed in the case body 202. The first retainer 208 has the terminal retaining portion 281 and the terminal holding portion 282. The first retainer 208 is accommodated in the case body 202 together with the second retainer 209.

(Terminal Retaining Portion)

The terminal retaining portion 281 is a member that retains the top end portions 271 of the plurality of first terminals 207. As shown in FIGS. 4A and 4B, the terminal retaining portion 281 has the movement restraining surface 281A, a plurality of protrusions 281B and a wall portion 281C.

The movement restraining surface 281A supports the band portions 271A of the top end portions 271 of the plurality of first terminals 207 in the Z-axis direction. The plurality of protrusions 281B protrude in the Z-axis direction from the movement restraining surface 281A. The protrusions 281B are inserted in the penetration openings 271C of the top end portions 271 respectively.

The wall portion 281C encloses the plurality of band portions 271A so as to restrain a movement in the Y-axis direction (i.e. in a width direction) and a movement toward a protruding portion 271B side of the band portion 271A. The wall portion 281C has a plurality of recessed portions that are recessed in the Z-axis direction. The protruding portions 271B of the top end portions 271 protrude from the terminal retaining portion 281 through these recessed portions respectively.

(Terminal Holding Portion)

The terminal holding portion 282 is a member into which the plurality of first terminals 207 are inserted.

The terminal holding portion 282 has the plurality of penetration holes 282A. The plurality of penetration holes 282A extend in the X-axis direction. By the fact that the plurality of first terminals 207 are inserted into the plurality of penetration holes 282A respectively, the band portions 271A are accommodated or fitted in respective small holes or slots (i.e. cut-out portions) that are formed at the penetration holes 282A, thereby restraining a movement in the Z-axis direction of each first terminal 207.

Therefore, the first retainer 208 forms a retainer mechanism that restrains a movement, in the center axis direction of the case body 202 (i.e. the X-axis direction) and a direction that is perpendicular to the center axis of the case body 202 and parallel to the plate surface of the circuit board 206 (i.e. the Y-axis direction), of each first terminal 207 in a state in which the first retainer 208 is not engaged with the second retainer 209.

As shown in FIGS. 2 and 4B, the terminal holding portion 282 is a different member from the terminal retaining portion 281, and is coupled to the terminal retaining portion 281. More specifically, an end portion 281D of the terminal retaining portion 281 is inserted into the terminal holding portion 282, and an engaging portion provided at the terminal holding portion 282 is engaged with an engaged portion provided at the terminal retaining portion 281, then the terminal holding portion 282 is coupled to the terminal retaining portion 281. The terminal retaining portion 281 and the terminal holding portion 282 are made of, for instance, resin.

<Second Retainer>

The second retainer 209 is an insulating member placed in the case body 202 together with the first retainer 208. The second retainer 209 is made of, for instance, resin. The second retainer 209 in the present embodiment is a resin-molded component in which the plurality of second terminals 210 are inserted. The second retainer 209 is configured to be able to be engaged with the first retainer 208. The terminal core formed by the second retainer 209 and the second terminals 210 in this mariner is placed in the case body 202.

The second retainer 209 has, as shown in FIG. 2, the plurality of sandwiching surfaces 209A that sandwich and support the top end portions 271 of the plurality of first terminals 207 in cooperation with the terminal retaining portion 281 of the first retainer 208, the two positioning portions 209B that maintain a position relationship with the circuit board 206, the two recessed portions 209C that are recessed inwards in the Y-axis direction, two engaging portions 209D that are engaged with the terminal retaining portion 281, and the second terminals 210.

The plurality of sandwiching surfaces 209A are provided at a terminal inserting portion 203 side of a body of the second retainer 209. More specifically, the plurality of sandwiching surfaces 209A are provided on a surface, located at a circuit board 206 side, of the second retainer 209, and each sandwiching surface 209A faces the movement restraining surface 281A of the terminal retaining portion 281.

The plurality of sandwiching surfaces 209A sandwich and support the respective top end portions 271 of the plurality of first terminals 207 in cooperation with the opposing terminal retaining portion 281. That is, the first retainer 208 and the second retainer 209 are configured to restrain the movements in all directions of the plurality of first terminals 207 in a state in which the first retainer 208 and the second retainer 209 are engaged with each other.

The two positioning portions 209B are each a rod-like protrusion that extends parallel to the Z-axis from the body of the second retainer 209 toward the circuit board 206. Each of the positioning portions 209B is formed so as to be able to be fitted into the board penetration hole 206A of the circuit board 206. The two positioning portions 209B are provided at both end portions in the Y-axis direction of the second retainer 209 one by one.

The two recessed portions 209C are formed at both end side surfaces in the Y-axis direction of the second retainer 209 respectively. Each recessed portion 209C is a part formed by opposing two walls that face to each other in the Z-axis direction. Each recessed portion 209C has a groove shape that extends in the X-axis direction.

The recessed portions 209C are engaged with the respective ridge lines 202B of the case body 202. Each of the recessed portions 209C is configured so as to be able to slide with respect to the ridge 202B in the X-axis direction. Therefore, the two recessed portions 209C and the two ridge lines 202B form a guide that guides the terminal core formed by the first retainer 208 and the second retainer 209 in the center axis direction of the case body 202.

The two engaging portions 209D are each a nail that is engaged with the first retainer 208. The engaging portions 209D each extend parallel to the Z-axis from end portions in the Y-axis direction of the body of the second retainer 209 toward the terminal retaining portion 281 of the first retainer 208, and tip ends of the engaging portions 209D are bent inwards in the Y-axis direction. As shown in FIG. 5B, the two engaging portions 209D are engaged with the terminal retaining portion 281 from both outer sides in the Y-axis direction, thereby fixing the second retainer 209 to the first retainer 208 so as to hold the terminal retaining portion 281 from both sides in the Y-axis direction.

As shown in FIG. 2, the plurality of second terminals 210 are retained by the second retainer 209. The plurality of second terminals 210 have top end portions 210A that are inserted into and soldered to a plurality of through holes 206C of the circuit board 206 respectively and band portions 210B that are placed in the connector 202A. The plurality of second terminals 210 are arranged parallel to each other in a direction in which longitudinal directions of the band portions 210B are parallel to the center axis direction of the case body 202.

Each of the top end portions 210A extends in the Z-axis direction from the body of the second retainer 209 toward the circuit board 206. An end portion, located at an opposite side to the top end portion 210A, of each band portion 210B protrudes in the X-axis direction from the body of the second retainer 209, and is exposed without being covered with the second retainer 209.

<Seal Member>

As shown in FIG. 2, the seal member 211 is an annular member that seals a gap between the first retainer 208 and the case body 202. In the present embodiment, the seal member 211 is fitted on or secured to an outer peripheral surface of the terminal holding portion 282 of the first retainer 208. The seal member 211 is made of, for instance, rubber.

<Manufacturing Method>

A manufacturing method namely an assembling method, of the circuit connection device 201 will be explained here.

The manufacturing method of the circuit connection device 201 includes a first process in which the first retainer 208 is assembled, a second process in which the second retainer 209 is engaged with the first retainer 208 and a third process in which the first retainer 208 and the second retainer 209 are inserted into the case body 202.

(First Process)

In this process, first, the first terminals 207 are inserted into the terminal inserting portion 203. At this time, the terminal inserting portion 203 is positioned so as to be shifted to an overlapping position where the terminal inserting portion 203 overlaps sheaths of the connecting cables 204. Subsequently, the terminal retaining portion 281 and the terminal holding portion 282 are coupled to each other, then the first retainer 208 is assembled. Further, the seal member 211 is secured to the terminal holding portion 282.

(Second Process)

In this process, first, the plurality of first terminals 207 are inserted into the terminal holding portion 282, and the plurality of top end portions 271 are retained by the terminal retaining portion 281. Subsequently, the top end portions 271 of the plurality of first terminals 207 are bent in the Z-axis direction. In this state, the second retainer 209 is engaged with the first retainer 208. Further, the circuit board 206 is mounted to the second retainer 209 (the second retainer 209 is mounted on the circuit board 206) by or through the two positioning portions 209B.

At this time, the top end portions 271 of the plurality of first terminals 207 and the top end portions 210A of the plurality of second terminals 210 are inserted into the plurality of through holes 206B and the plurality of through holes 206C of the circuit board 206 respectively. These terminals are electrically connected to the circuit board 206 by soldering.

(Third Process)

In this process, a circuit component including the first retainer 208, the second retainer 209 and the circuit board 206 is inserted into the case body 202.

More specifically, the second terminals 210 are covered with the case body 202 so that the top ends, located at an opposite side to the terminal inserting portion 203, of the second terminals 210 are inserted into the opening of the case body 202. At this time, the circuit component is moved parallel to the X-axis with the two recessed portions 209C of the second retainer 209 being engaged with the two ridge lines 202B of the case body 202. Afterwards, the terminal inserting portion 203 is moved so as to slide up to a position at which the terminal inserting portion 203 is engaged with the case body 202 along the longitudinal direction of the case body 202 (i.e. along the X-axis direction).

In a state in which the terminal inserting portion 203 and the case body 202 are fixed, a position of the circuit board 206 with respect to the second retainer 209 is maintained by the two positioning portions 209B. Therefore, the circuit board 206 is held or maintained at a certain or predetermined position in the case body 202. In this manner, the circuit connection device 201 can be obtained.

[1-2. Effect]

According to the embodiment described above, the following effects can be obtained.

(1a) After fixing the second retainer 209 to the terminal inserting portion 203 through the first retainer 208, a relative position between the second retainer 209 and the circuit board 206 can be previously fixed before being inserted into the case body 202. Therefore, by inserting the terminal core (i.e. the first retainer 208 and the second retainer 209) and the circuit board 206 into the case body 202 together with the terminal inserting portion 203 and fitting the terminal inserting portion 203 to the case body 202, it is possible to maintain the terminal core and the circuit board 206 at an intended position.

(1b) Since the second retainer 209 has the recessed portions 209C engaged with the respective ridge lines 202B of the case body 202, even in a case where the inside of the case body 202 is long (i.e. even in a case where the circuit board 206 is long), the terminal core and the circuit board 206 can be smoothly inserted into the case body 202. It is therefore possible to facilitate the positioning of the circuit board 206 and the terminal core (the positioning between the circuit board 206 and the terminal core) in the case body 202. Further, it is possible to prevent the circuit board 206 from striking against the inner surface of the case body 202 and from breaking when being inserted into the case body 202.

### 2. Second Embodiment

### [2-1. Configuration]

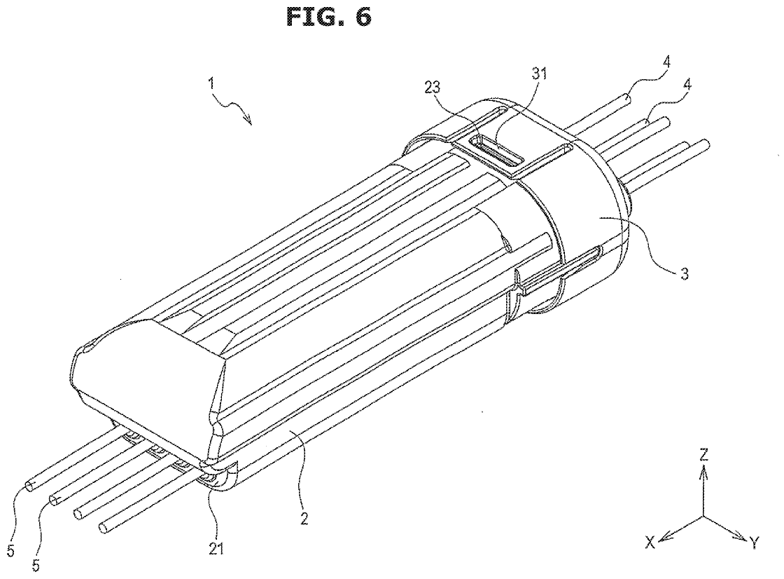

A circuit connection device 1 shown in FIG. 6 is a device that protects a circuit board for controlling or driving an electronic device and electrically connects the circuit board to the electronic device and to a control device.

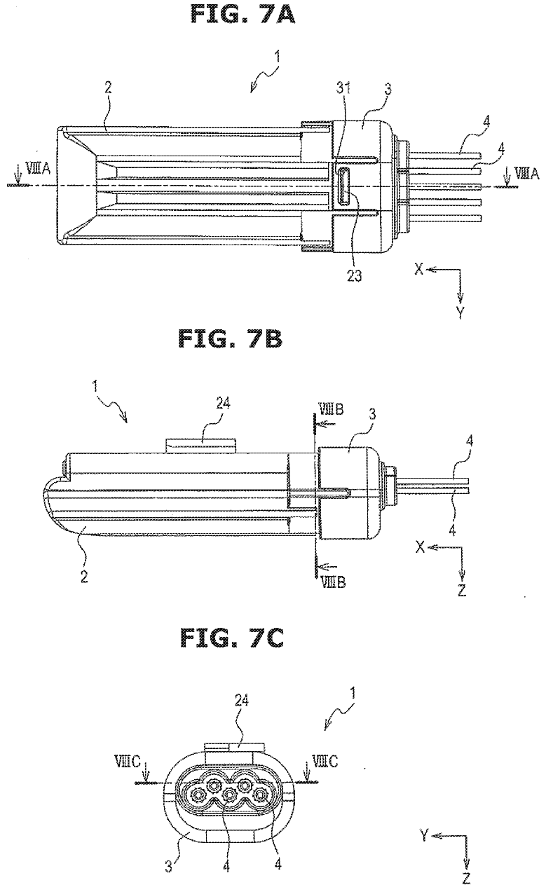

The circuit connection device 1 has, as shown in FIGS. 6, 7A, 7B, 7C, 8A, 8B and 8C, a case body 2, a terminal inserting portion 3, a plurality of first connecting cables 4, a plurality of second connecting cables 5, a circuit board 6, a plurality of first terminals 7 and a terminal core 8. In the drawings, an X-axis is an axis that is parallel to a center axis of the case body 2, a Z-axis is an axis that is perpendicular to a plate surface of the circuit board 6, and a Y-axis is an axis that is perpendicular to the X-axis and the Z-axis.

<Case Body>

The case body 2 is a bottomed tubular body whose one end is an opening end and whose other end is a closed end. The case body 2 is usually made of resin.

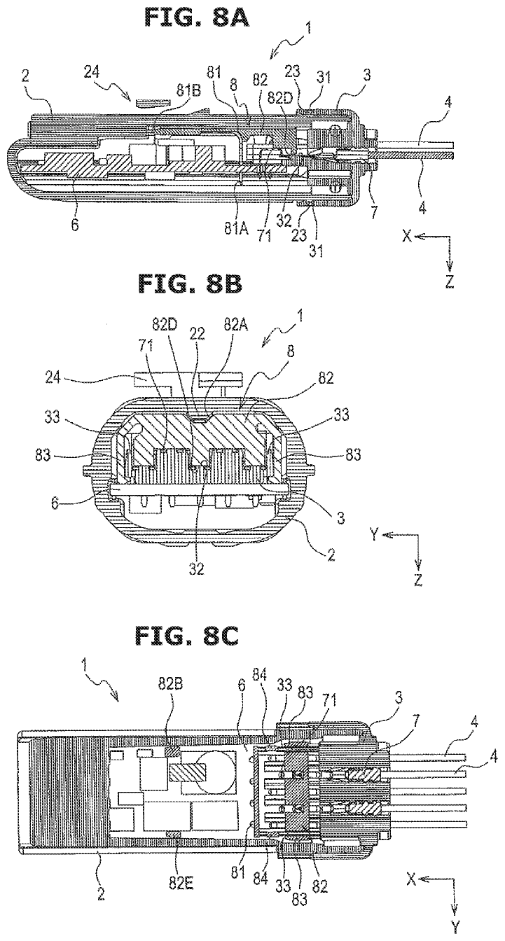

As shown in FIG. 6, a direction of the center axis of the case body 2 is identical with a longitudinal direction (a direction of the X-axis in the drawings). As shown in FIGS. 8A, 8B and 8C, the circuit board 6 and the terminal core 8 are accommodated in an inside space of the case body 2. Here, the center axis of the case body 2 means an axis that passes through a center of the case body 2 and extends from one end side to the other end side of the case body 2 (i.e. extends from the opening to an opposite side to the opening).

The plurality of first connecting cables 4 that are connected to the circuit board 6 are inserted into the case body 2 in the X-axis direction. More specifically, the case body 2 is provided, on its bottom surface 21 located at the opposite side to the opening, with a plurality of penetration holes, and the plurality of second connecting cables 5 are inserted into these plurality of penetration holes.

The case body 2 has, as shown in FIG. 8B, a ridge line 22 that is formed on an inner surface, facing to the circuit board 6, of the case body 2 and extends parallel to the X-axis. This ridge line 22 restrains a movement in the Y-axis direction of the terminal core 8 by a top end portion of the ridge line 22 being inserted or fitted into a groove-shaped guide 82A of the terminal core 8.

An area, which is a cross section (an Y-Z surface) that is perpendicular to the center axis of the case body 2, of an inside space of the case body 2 is gradually smaller from the opening of the case body 2 toward an opposite side to the opening. More specifically, a width in the Y-axis direction of an area where the circuit board 6 is accommodated is gradually smaller (narrower) from the opening toward the bottom surface 21.

The case body 2 has, on an cuter surface thereof, a mounting portion 24 to which a bracket etc. for securing the circuit connection device 1 to other member such as a vehicle body of a vehicle are mounted. In the present embodiment, the drawings show, as an example, a mechanism to mount the bracket to the mounting portion 24 in a sliding manner.

<Terminal Inserting Portion>

The terminal inserting portion 3 is a bottomed tubular body whose length in the center axis direction is shorter than that of the case body 2. The terminal inserting portion 3 is usually made of resin, which is the same as the case body 2

The terminal inserting portion 3 closes the opening of the case body 2 by being fitted onto a distal end at the opening side of the case body 2. More specifically, the terminal inserting portion 3 has a plurality of fitting holes 31, and fitting nails 23 of the case body 2 are fitted into these fitting holes 31, then the terminal inserting portion 3 is fixed to the case body 2.

As shown in FIGS. 8A and 8C, the plurality of first terminals 7 and the plurality of first connecting cables 4 to which the plurality of first terminals 7 are connected are inserted into the terminal inserting portion 3. More specifically, the terminal inserting portion 3 is provided, at a bottom thereof, with a plurality of penetration holes, and the plurality of first terminals 7 and the plurality of first connecting cables are inserted into these plurality of penetration holes.

As shown in FIGS. 8A and 8B, the terminal inserting portion 3 has, at an inside thereof a plurality of movement restraining surfaces 32 that support top end portions 71 of the plurality of first terminals 7 respectively. The plurality of movement restraining surfaces 32 each have a protrusion that protrudes in the Z-axis direction. Each of the movement restraining surfaces 32 is configured so that the top end portion 71 of the first terminal 7 is engaged with the protrusion. The plurality of movement restraining surfaces 32 form a retainer mechanism that restrains a movement in the center axis direction of the case body 2 of each first terminal 7.

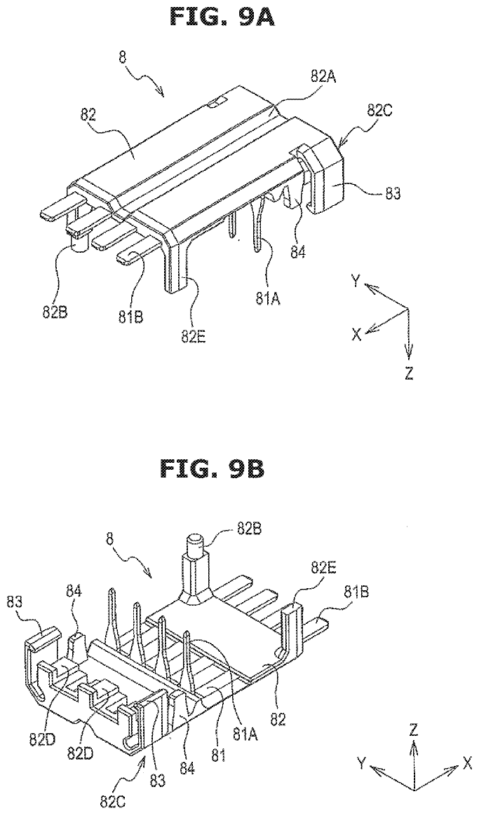

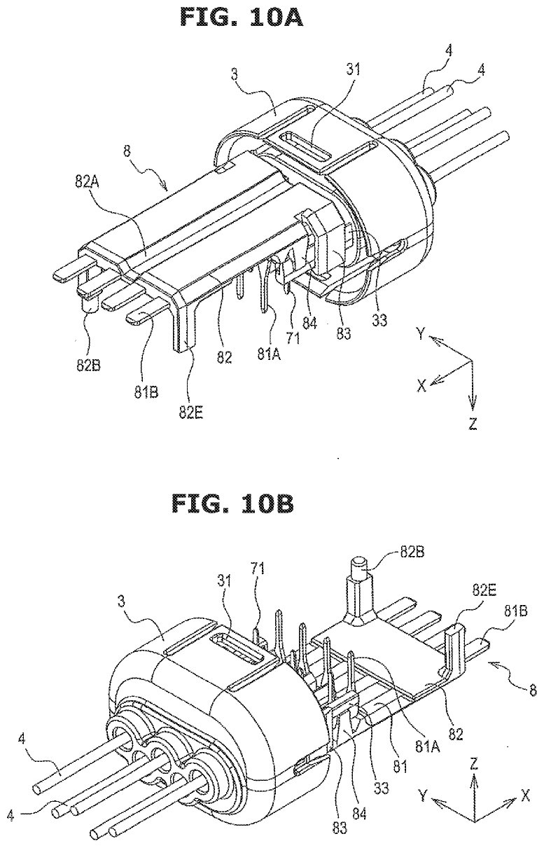

Further, as shown in FIGS. 10A and 10B, the terminal inserting portion 3 has a pair of protruding plates 33 that protrude inwards in the X-axis direction (i.e. toward a case body 2 side). An engaging portion 82C (see FIGS. 9A and 9B) of a retainer 82 is engaged with the pair of protruding plates 33.

Circuit Board>

The circuit board 6 has a rectangular outside shape. The circuit board 6 is accommodated in the case body 2 so that a longitudinal direction of the circuit board 6 is parallel to the center axis direction of the case body 2. A plurality of electronic components are mounted on the circuit board 6.

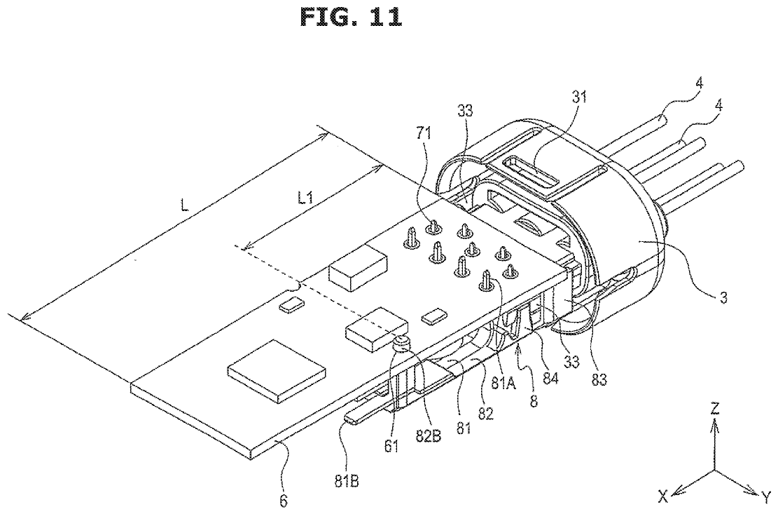

As shown in FIGS. 8A and 11, the plurality of first terminals 7 and a plurality of second terminals 81 are electrically connected to the circuit board 6. The circuit board 6 sends and receives signals between the circuit board 6 and the device that is electrically connected to the plurality of first connecting cables 4 to which the plurality of first terminals 7 are electrically connected or the plurality of second connecting cables 5 to which the plurality of second terminals 81 are electrically connected, and also supplies and receives power between the circuit board 6 and the device.

As shown in FIG. 11, the circuit board 6 has a positioning board penetration hole 61 into which a protrusion 82B of the terminal core 8 is fitted. A width in the Y-axis direction of the circuit board 6 is smaller (narrower) toward the bottom surface 21 side of the case body 2 (i.e. toward an opposite side to the terminal inserting portion 3).

<First Terminal>

As shown in FIG. 8A, each of the plurality of first terminals 7 is a crimping terminal that is fixed to a tip end (i.e. a core wire portion) of the first connecting cable 4. The top end portions 71, located at an opposite side to the first connecting cables 4, of the plurality of first terminals 7 are inserted into and soldered to a plurality of through holes of the circuit board 6 respectively.

Crimping portions of the first terminals 7 are inserted into the respective penetration holes of the terminal inserting portion 3. The top end portions 71 of the first terminals 7 extend along the penetration holes of the terminal inserting port ion 3 toward the inside of the case body 2. And, as shown in FIG. 8B, the top end portions 71 of the first terminals 7 are sandwiched and supported between the movement restraining surfaces 32 of the terminal inserting portion 3 and a plurality of sandwiching surfaces 82D of the retainer 82 respectively. More specifically, each of the top end portions 71 is provided with a penetration hole that penetrates the top end portion 71 in the Z-axis direction, and the protrusion formed on each movement restraining surface 32 is fitted into this penetration hole. A portion, except this penetration hole, of each top end portion 71 is sandwiched and supported between the movement restraining surface 32 and the sandwiching surface 82D.

<Terminal Core>

The terminal core 8 is a member that is placed in the case body 2 and electrically connects the second connecting cables 5 and the circuit board 6. The terminal core 8 has a positioning function of the circuit board 6 in the case body 2.

The terminal core 8 has the plurality of second terminals 81 and the insulating retainer 82 that supports the plurality of second terminals 81.

The plurality of second terminals 81 are made of, for instance, metal. As this material, for instance, copper alloy, such as brass (Cu—Zn series), phosphor bronze (Cu—Sn—P series), beryllium copper (Cu—Be series) and Corson copper (Cu—Ni—Si series), can be used.

The retainer 82 is made of, for instance, resin. As this resin, for instance, crystalline resin, such as polyamide (PA), polybutylene terephthalate (PBT) and polyphenylene sulfide (PPS), can be used. Typically, the retainer 82 is a resin-molded component in which the plurality of second terminals 81 are inserted.

(Second Terminal)

As shown in FIGS. 9A and 9B, the plurality of second terminals 81 have top end portions 81A that are inserted into and soldered to through holes of the circuit board 6 respectively and band portions 815 that are electrically connected to the second connecting cables 5 respectively. The plurality of second terminals 81 are arranged parallel to each other in a direction in which longitudinal directions of the band portions 81B are parallel to the longitudinal direction of the case body 2.

Each of the top end portions 81A is formed so that its width is smaller (narrower) than that of the band portion 81B. Each of the top end portions 81A extends in the Z-axis direction from the body of the retainer 82 toward the circuit board 6. An end portion, located at an opposite side to the top end portion 81A, of each band portion 81B protrudes in the X-axis direction from an end portion, located at a bottom surface 21 side of the case body 2, of the retainer 82, and is exposed without being covered with the retainer 82.

(Retainer)

The retainer 82 has a plate body. The retainer 82 is placed close to the inner surface of the case body 2 so that one side surface of the body faces the circuit board 6.

As shown in FIG. 9A, the retainer 82 has the groove-shaped guide 82A that extends in the X-axis direction, a positioning portion 82B that maintains a position relationship with the circuit board 6, the engaging portion 82C that is engaged with the terminal inserting portion 3 and the plurality of sandwiching surfaces 82D that sandwich and support the top end portions 71 of the crimping terminals in cooperation with the terminal inserting portion 3.

As shown in FIGS. 9A and 10A, the guide 82A is formed at the middle in the Y-axis direction on a surface, located at an opposite side to the circuit board 6 (i.e. at an inner surface side of the case body 2), of the body of the retainer 82. A cross section shape of the guide 82A is a trapezoid as shown in FIG. 8B, and its shape does not change along the X-axis direction. The guide 82A extends in the x-axis direction from one end up to the other end of the retainer 82. The guide 82A is engaged with the ridge line 22 of the case body 2.

The positioning portion 82B is formed by the single rod-like protrusion 82B that extends parallel to the Z-axis from the body of the retainer 82 toward the circuit board 6. The protrusion 82B is formed so as to be able to be fitted into the board penetration hole 61 of the circuit board 6. The protrusion 82B is formed at an end portion in the Y-axis direction of the retainer 82. Further, at an end portion, located at an opposite side to the protrusion 82B in the Y-axis direction, of the retainer 82, a rod-like auxiliary protrusion 82E that extends parallel to the protrusion 82B is provided.

As shown in FIG. 11, when a length of the circuit board 6 in the center axis direction of the case body 2 is L, it is preferable that positioning of the circuit board 6 by the protrusion 82B be made (namely that the protrusion 82B be engaged with the board penetration hole 61 of the circuit board 6) at a position that is L/3 or more away from an end portion, located at a terminal inserting portion 3 side, of the circuit board 6. That is, it is preferable that a distance L1 in a direction parallel to the length L from the end portion, located at the terminal inserting portion 3 side, of the circuit board 6 to the protrusion 82B be set to L/3 or more. With this setting, it is possible to effectively prevent the position of the circuit board 6 from shifting in the case body 2.

The engaging portion 82C is formed by a pair of nails 83 that are engaged with the pair of protruding plates 33 of the terminal inserting portion 3 respectively and a pair of stoppers 84.

The pair of nails 33 each extend parallel to the Z-axis direction from the both end portions in the Y-axis direction of the body of the retainer 82 toward the circuit board 6, and tip ends of the nails 83 are bent inwards in the Y-axis direction. As shown in FIG. 8B, the tip ends of the pair of nails 83 are engaged with the pair of protruding plates 33 from both outer sides in the Y-axis direction, thereby fixing the terminal core 8 to the terminal inserting portion 3 as to hold the terminal inserting portion 3 from both sides in the Y-axis direction.

The pair of stoppers 84 are provided close to the pair of nails 83 at the both end portions in the Y-axis direction of the body of the retainer 82. The pair of stoppers 84 are each a protrusion that protrudes parallel to the Z-axis direction toward the circuit board 6. A thickness in the Y-axis direction of the stopper 84 is greater than that of the nail 83. By the fact that the pair of stoppers 84 are engaged with respective recessed portions, which are recessed in the Z-axis direction, of the pair of protruding plates 33, a movement in the X-axis direction of the terminal core 8 is restrained.

The plurality of sandwiching surfaces 82D are formed at a portion, located at a terminal inserting portion 3 side, of the body of the retainer 82. More specifically, the plurality of sandwiching surfaces 82D, Z-axis direction positions of which are different, are formed in a staggered configuration at the portion, located at a circuit board 6 side, of the retainer 82. The plurality of sandwiching surfaces 82D sandwich and support the respective top end portions 71 of the plurality of first terminals 7 in cooperation with the opposing movement restraining surfaces 32 between the first terminals 7 and the movement restraining surfaces 32.

<Manufacturing Method>

A manufacturing method, namely an assembling method, of the circuit connection device 1 will be explained here.

The manufacturing method of the circuit connection device 1 includes a first process in which the terminal core 8 is fixed to the terminal inserting portion 3, a second process in which the circuit board 6 is mounted to the terminal core 8 having been fixed to the terminal inserting portion 3 and a third process in which the terminal core 8 having mounted thereto the circuit board 6 is inserted into the case body 2.

(First Process)

In this process, first, the plurality of first terminals 7 connecting to the plurality of first connecting cables 4 are inserted into the terminal inserting portion 3, and the top end portions 71 of the plurality of first terminals 7 are bent in the Z-axis direction.

Next, as shown in FIGS. 10A and 10B, the terminal core 8 is fitted to the pair of protruding plates 33 of the terminal inserting portion 3 in the Z-axis direction so as to overlap the pair of protruding plates 33, and the pair of nails 83 are engaged with the pair of protruding plates 33. At this time, the penetration holes of the top end portions 71 of the first terminals 7 are each fitted onto the protrusions of the movement restraining surfaces 32 of the terminal inserting portion 3 respectively. With this, each position in the X-axis direction of the plurality of first terminals 7 is fixed.

(Second Process)

In this process, as shown in FIG. 11, the circuit board 6 is mounted to the terminal core 8 in the Z-axis direction so as to ride on the terminal core 8 so that the protrusion 82B of the terminal core 8 is fitted into the board penetration hole 61 of the circuit board 6.

At this time, the top end portions 71 of the plurality of first terminals 7 and the top end portions 81A of the plurality of second terminals 81 are inserted into the plurality of through holes of the circuit board 6 respectively. These terminals are electrically connected to the circuit board 6 by soldering.

(Third Process)

In this process, a circuit component including the terminal inserting portion 3, the terminal core 8 and the circuit board 6 shown in FIG. 11 is inserted into the case body 2. More specifically, a top end, located at an opposite side to the terminal inserting portion 3, of the circuit board 6 is inserted into the opening of the case body 2, and is moved as it is so as to slide along the longitudinal direction of the case body 2 (i.e. along the X-axis direction).

At this time, the circuit component is moved parallel to the X-axis with the guide 82A of the terminal core 8 being engaged with the ridge line 22 of the case body 2. Here, before inserting the circuit component into the case body 2, parts of the second connecting cables 5 are previously set in the respective penetration holes formed on the bottom surface 21 of the case body 2. More specifically, the second connecting cables 5 are each set in the respective penetration holes so that a crimping terminal (not shown) fixed to a tip end (i.e. a core wire portion) of each second connecting cable 5 is set at a predetermined position of the penetration hole formed on the bottom surface 21.

As shown in FIG. 8, when the terminal inserting portion 3 is inserted up to a position at which the opening end of the case body 2 contacts a bottom of the terminal inserting portion 3, the plurality of fitting nails 23 of the case body 2 are fitted into the plurality of fitting holes 31 of the terminal inserting portion 3, then the terminal inserting portion 3 and the case body 2 are fixed together. Further, by the fact that the terminal inserting portion 3 and the case body 2 are fixed together, the band portions 81B of the plurality of second terminals 81 of the terminal core 8 are engaged with respective band portion fixing portions of the crimping terminals (not shown) fixed to the tip ends of the second connecting cables 5. The plurality of second terminals 81 and the plurality of second connecting cables 5 are then electrically connected to each other.

In a state in which the terminal inserting portion 3 and the case body 2 are fixed together, a movement of the terminal core 8 with respect to the terminal inserting portion 3 is restrained by the engaging portion 82C and the pair of protruding plates 33 being engaged with each other. Further, a position of the circuit board 6 with respect to the terminal core 8 is maintained by the protrusion 82B. With the above structures, the circuit board 6 is held or maintained at a certain or predetermined position in the case body 2. In this manner, the circuit connection device 1 can be obtained.

Here, anti-seizing agent is applied to the outer surface of the case body 2. Further, a metal fitting (e.g. a bracket for screw fixing) for fixing the circuit connection device 1 to other member is mounted to the mounting portion 24 of the case body 2.

[2-2. Effect]

According to the embodiment described above, the following effects can be obtained.

(2a) After engaging the terminal core 8 with the terminal inserting portion 3 by the pair of nails 83, a relative position between the terminal core 8 and the circuit board 6 can be previously fixed by the protrusion 82B before being inserted into the case body 2. Therefore, by inserting the terminal core 8 and the circuit board 6 into the case body 2 together with the terminal inserting portion 3 and fitting the terminal inserting portion 3 to the case body 2, it is possible to maintain the terminal core 8 and the circuit board 6 at an intended position.

(2b) Since the terminal core 8 has the guide 82A engaged with the ridge line 22 of the case body 2, even in a case where the inside of the case body 2 is long (i.e. even in a case where the circuit board 6 is long), the terminal core 8 and circuit board 6 can be smoothly inserted into the case body 2. It is therefore possible to facilitate the positioning of the circuit board 6 and the terminal core 8 (the positioning between the circuit board 6 and the terminal core 8) in the case body 2. Further, it is possible to prevent the circuit board 6 from striking against the inner surface of the case body 2 and from breaking when being inserted into the case body 2.

(2c) The positioning between the terminal core 8 and the circuit board 6 is made by a relatively simple structure of the fitting of the protrusion 82B into the board penetration hole 61. It is therefore possible to improve the workability of the positioning between the terminal core 8 and the circuit board 6 while suppressing cost of components.

(2d) Since the engaging portion 82C has the pair of nails 83, it is possible to fix the terminal core 8 to the terminal inserting portion 3 easily and surely.

(2e) Since the crimping terminal is connected to the tip end of each first connecting cable 4, it is possible to reduce error affecting minute electric current that is transmitted and received when the plurality of first connecting cables 4 are connected to a sensor. That is, if the plurality of first connecting cables 4 and the circuit board 5 are connected by contact connection, a contact resistance of a terminal contact portion changes due to environmental load such as vibration load. However, by using the crimping terminal, the change of the contact resistance can be suppressed.

(2f) The retainer 82 of the terminal core 8 and the terminal inserting portion 3 form the retainer mechanism that restrains the movements in the X-axis direction of the top end portions 71 of the plurality of crimping terminals. It is thus possible to prevent the crimping terminal from coming off from the first connecting cable 4.

(2g) The area, which is the cross section that is perpendicular to the center axis of the case body 2, of the inside space of the case body 2 is gradually smaller from the opening of the case body 2 toward the opposite side to the opening. Hence, this facilities the insertion of the circuit board 6. Further, positioning accuracy of the terminal core 8 and the circuit board 6 in the longitudinal direction in the case body 2 can be improved.

### 3. Third Embodiment

### [3-1. Configuration]

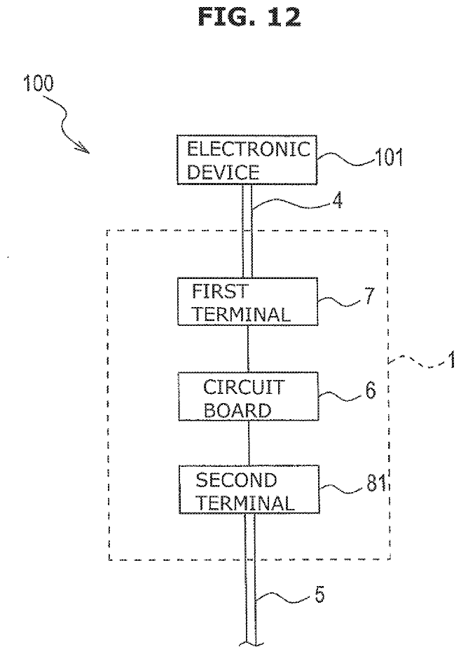

Electronic equipment 100 shown in FIG. 12 has the circuit connection device 1 and an electronic device 101 electrically connected to the plurality of first terminals 7 through the first connecting cables 4.

As the electronic device 101, it is a heater, a sensor that detects a physical quantity or a chemical quantity, and so on. As the sensor, for instance, it is a gas sensor that detects an oxygen concentration in exhaust and a temperature sensor that detects temperature of fluid to be measured.

Here, the plurality of second terminals 81 of the circuit connection device 1 are connected to an electronic control device (not shown) that performs, for instance, control of a vehicle, through the plurality of second connecting cables 5.

[3-2. Effect]

According to the embodiment described above, the following effects can be obtained.

(3a) Because of ease of positioning of the circuit board 6, it is possible to improve reliability of connection between the electronic device 101 and the circuit board 6.

### 4. Other Embodiment

The present invention has been explained above on the basis of the above embodiments. However, the present invention is not limited to the above embodiments, but needless to say, includes variety of modifications.

(4a) In the circuit connection device 201 of the above embodiment, as shown in FIG. 3B, ridge lines 209E could be provided at the second retainer 209, and recessed portions 202C that are engaged with these ridge lines 209E could be provided at the case body 202. Further, instead of the ridge lines 202B and 209E, one or a plurality of pin-shaped protrusions might be used. Then, by fitting the protrusion into a groove that extends in the X-axis direction, a guide that guides the terminal core in the axis direction of the case body 202 is formed. The groove forming the guide could be divided in the X-axis direction

(4b) In the circuit connection device 1 of the above embodiment, the circuit board 6 could be provided with two or more board penetration holes, and the positioning portion 82B of the retainer 82 could include two or more protrusions that are fitted into the two or more board penetration holes of the circuit board 6. Further, the positioning portion 82B could include a positioning structure except the protrusion, such as a clip structure that holds or grasps the circuit board 6.

(4c) In the circuit connection device 1 of the above embodiment, the engaging portion 82C of the retainer 82 does not necessarily have the pair of nails 83. As long as the engaging portion 82C of the retainer 82 can be engaged with a part of the terminal inserting portion 3, an engagement structure except the nail can be employed.

(4d) In the circuit connection device 1 of the above embodiment, the first terminal 7 is not necessarily the crimping terminal, but other terminal can be used. However, as mentioned above, it is preferable to use the crimping terminal when using the sensor signal.

(4e) In the circuit connection device 1 of the above embodiment, the restraint of the movement in the X-axis direction of the top end portion 71 of the plurality of first terminal 7 is not necessarily required. The top end portion 71 of the plurality of first terminal 7 could be connected to the circuit board 6 with the top end portion 71 being free without being sandwiched by the terminal inserting portion 3 etc.

(4f) In the circuit connection device 1 of the above embodiment, the area, which is the cross section that is perpendicular to the center axis of the case body 2, of the inside space of the case body 2 is not necessarily smaller from the opening of the case body 2 toward the opposite side to the opening, but could be constant. Further, as for the width in the Y-axis direction of the circuit board 6, it is not necessarily smaller (narrower) toward the bottom surface 21 side of the case body 2.

(4g) A function which one component of the above embodiments has could be realized by a plurality of components, and functions which a plurality components have could be realized by one component. In addition, a part of the above configuration or structure could be omitted. Moreover, at least a part of the above configuration or structure could be added to a configuration or structure of other embodiment described above, or might be replaced. The present invention includes all design modifications and equivalents belonging to the technical scope of the present invention.

1. A circuit connection device for connecting a circuit to an electronic device, comprising:
one or a plurality of first terminals;
a circuit board to which the one or the plurality of first terminals is electrically connected;
a tubular case body accommodating therein the circuit board and having at one end thereof an opening;
a terminal inserting portion having one or a plurality of penetration holes and closing the opening of the case body;
a terminal core placed in the case body; and
a guide configured to guide the terminal core in an axis direction of the case body, and wherein
the one or the plurality of first terminals is inserted into the one or the plurality of penetration holes of the terminal inserting portion, and
the terminal core has:
one or a plurality of second terminals electrically connected to the circuit board; and
an insulating retainer retaining the one or the plurality of second terminals, and wherein
the retainer has a positioning portion configured to maintain a position relationship with the circuit board.

2. The circuit connection device as claimed in claim 1, wherein:
the circuit board has at least one board penetration hole, and
the positioning portion includes at least one protrusion that is fitted into the at least one board penetration hole of the circuit board.

3. The circuit connection device as claimed in claim 1, wherein:
when a length of the circuit board in the axis direction of the case body is L, positioning of the circuit board by the positioning portion is made at a position that is L/3 or more away from an end portion, located at a terminal inserting portion side, of the circuit board.

4. The circuit connection device as claimed in claim 1, wherein:
the terminal inserting portion has a protruding plate that protrudes inwards in the axis direction of the case body,
the retainer has an engaging portion that is engaged with the terminal inserting portion, and
the engaging portion includes at least one nail that is engaged with the protruding plate of the terminal inserting portion.

5. The circuit connection device as claimed in claim 1, wherein:
the first terminal is a crimping terminal that is fixed to a tip end of a connecting cable, and
the terminal inserting portion has a movement restraining surface with which a top end portion of the crimping terminal is engaged.

6. The circuit connection device as claimed in claim 1, wherein:
an area, which is a cross section that is perpendicular to the axis direction of the case body, of an inside space of the case body is smaller from the opening of case body toward an opposite side to the opening.

7. Electronic equipment having the circuit connection device
claimed in claim 1 and an electronic device that is electrically connected to the one or the plurality of first terminals.
